(19) United States
(12) Patent Application Publication
(10) Pub. No.: US 2025/0234677 A1
(43) Pub. Date: Jul. 17, 2025

(54) METHOD OF MANUFACTURING SEMICONDUCTOR CHIP

(71) Applicant: Innolux Corporation, Miaoli County (TW)

(72) Inventors: Jan-Hsiang Yang, Miaoli County (TW); Tzu-Min Yan, Miaoli County (TW)

(73) Assignee: Innolux Corporation, Miaoli County (TW)

(21) Appl. No.: 18/979,507

(22) Filed: Dec. 12, 2024

Related U.S. Application Data
(60) Provisional application No. 63/620,889, filed on Jan. 15, 2024.

(30) Foreign Application Priority Data
Sep. 13, 2024 (CN) 202411286522.2

(51) Int. Cl. H10H 20/01

(52) U.S. Cl. CPC H10H 20/0363; H10H 20/032; H10H 20/0364

(57) ABSTRACT

The disclosure provides a method of manufacturing a semiconductor chip. The method of manufacturing the semiconductor chip includes the following steps: providing a first carrier; transferring a semiconductor die to the first carrier, wherein the semiconductor die has a surface and another surface opposite to each other; forming a filling layer on a side surface of the semiconductor die; forming a reflective layer on the semiconductor die and the side surface, wherein the reflective layer includes a first part and a second part, the first part is disposed on the surface of the semiconductor die, and the second part is disposed on the filling layer; and forming a conductive layer on the another surface of the semiconductor die. The method of manufacturing the semiconductor chip of the disclosure may directly perform detection after the semiconductor chip is transferred.

### CROSS-REFERENCE TO RELATED APPLICATION

This application claims the priority benefit of U.S. provisional application Ser. No. 63/620,889, filed on Jan. 15, 2024, and China application serial no. 202411286522.2, filed on Sep. 13, 2024. The entirety of each of the above-mentioned patent applications is hereby incorporated by reference herein and made a part of this specification.

### BACKGROUND

### Technical Field

The disclosure relates to a method of manufacturing a semiconductor chip, particularly to a method of manufacturing a semiconductor chip that may directly perform detection after the semiconductor chip is transferred.

### Description of Related Art

The electronic device or the splicing electronic device is widely applied in different fields such as communication, display, automotive, or aviation. With the rapid development of the electronic device, the electronic device is developing to become lighter and thinner, so the reliability or quality requirement for the electronic device is becoming higher.

### SUMMARY

The disclosure provides a method of manufacturing a semiconductor chip, which may directly perform detection after the semiconductor chip is transferred, to improve the transfer yield of the semiconductor chip.

According to an embodiment of the disclosure, the method of manufacturing a semiconductor chip includes the following steps: providing a first carrier; transferring a semiconductor die to the first carrier, wherein the semiconductor die has a surface and another surface opposite to each other; forming a filling layer on a side surface of the semiconductor die; forming a reflective layer on the semiconductor die and the side surface, wherein the reflective layer includes a first part and a second part, the first part is disposed on the surface of the semiconductor die, and the second part is disposed on the filling layer; and forming a conductive layer on the another surface of the semiconductor die.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1D are cross-sectional schematic views of the method of manufacturing a semiconductor chip in the first embodiment of the disclosure.

FIG. 2A to FIG. 2E are cross-sectional schematic views of the method of manufacturing a semiconductor chip in the second embodiment of the disclosure.

FIG. 3A to FIG. 3C are cross-sectional schematic views of the method of manufacturing a semiconductor chip in the third embodiment of the disclosure.

FIG. 4 is a cross-sectional schematic view of the semiconductor chip in the fourth embodiment of the disclosure.

FIG. 5 is a cross-sectional schematic view of the semiconductor chip in the fifth embodiment of the disclosure.

FIG. 6A to FIG. 6B are cross-sectional schematic views of the semiconductor chip in the sixth embodiment of the disclosure.

FIG. 7A to FIG. 7B are cross-sectional schematic views of the semiconductor chip in the seventh embodiment of the disclosure.

### DESCRIPTION OF THE EMBODIMENTS

The disclosure may be understood with reference to the following detailed description taken in conjunction with the drawings. It should be noted that for the ease of understanding by the reader and the conciseness of the drawings, multiple drawings of the disclosure only depict a portion of an electronic device, and specific elements in the drawings may not be drawn according to actual scale. Furthermore, the number and the size of each element in the drawings are illustrative only and are not intended to limit the scope of the disclosure.

In the following specification and claims, terms such as “containing” and “including” are open-ended terms and should thus be interpreted to mean “comprising but not limited to . . . ”.

It should be understood that when an element or a film layer is referred to as being “on” or “connected to” another element or film layer, the element or film layer may be directly on the other element or film layer or directly connected to the other element or film layer, or there may be an element or a film layer inserted between the two (case of indirect connection). In contrast, when an element or a film layer is referred to as being “directly on” or “directly connected to” another element or film layer, there is no element or film layer inserted between the two.

Although terms such as “first”, “second”, and “third” may be used to describe multiple constituent elements, the constituent elements are not limited by the terms. The terms are only used to distinguish a single constituent element from other constituent elements in the specification. The claims may not use the same terms, which may be replaced by first, second, third . . . in the order of declaration of the elements in the claims. Therefore, in the following specification, a first constituent element may be a second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, in the case where “about”, “approximately”, “substantially”, and “roughly” are not particularly described, the meanings of “about”, “approximately”, “substantially”, and “roughly” may still be implied.

In some embodiments of the disclosure, terms related to bonding and connection such as “connection” and “interconnection”, unless otherwise specified, may mean that two structures are in direct contact or may also mean that the two structures are not in direct contact, wherein there is another structure disposed between the two structures. Also, the terms related to bonding and connection may also include the case where the two structures are both movable or the two structures are both fixed. In addition, the term “coupling” includes any direct and indirect electrical connection means.

In some embodiments of the disclosure, an optical microscope (OM), a scanning electron microscope (SEM), a thin film thickness profilometer (α-step), an ellipsometer, or other suitable manners may be used to measure an area, a width, a thickness, or a height of each element or a distance or a spacing between elements. In detail, according to some embodiments, the scanning electron microscope may be used to obtain a cross-sectional structural image including the element to be measured and measure the area, the width, the thickness, or the height of each element or the distance or the spacing between the elements.

In the disclosure, the semiconductor chip may be applied in electronic device. The electronic device may include a display device, light emitting device, backlight device, virtual reality device, augmented reality (AR) device, antenna device, sensing device, tiled device, or any combination thereof, but not limited thereto. The display device may be a non-self-luminous display or a self-luminous display according to requirements, and may be a color display or a monochrome display according to requirements. The antenna device may be a liquid crystal type antenna device or a non-liquid crystal type antenna device. The sensing device may be a device for sensing capacitance, light, thermal energy, or ultrasound. The tiled device may be a display tiled device or an antenna tiled device, but not limited thereto. The electronic units in the electronic device may include passive components and active components, such as capacitors, resistors, inductors, diodes, transistors, etc. The diode may include a light emitting diode (LED) or a photodiode. The light emitting diode may include, for example, an organic light emitting diode (OLED), a mini LED, a micro LED, or a quantum dot LED, but not limited thereto. The transistor may include, for example, a top gate thin film transistor, a bottom gate thin film transistor, or a dual gate thin film transistor, but not limited thereto. The electronic device may also include fluorescence materials, phosphor materials, quantum dot (QD) materials, or other suitable materials according to requirements, but not limited thereto. The electronic device may have peripheral systems such as driving systems, control systems, light source systems, etc. to support display devices, antenna devices, wearable devices (including augmented reality or virtual reality devices, for example), vehicle-mounted devices (including car windshields, for example), or tiled devices. It should be noted that the electronic device may be any permutation and combination of the above, but not limited thereto. The following will use the semiconductor chip in the electronic device to explain the content of the disclosure, but this disclosure is not limited thereto.

It should be noted that in the following embodiments, without departing from the spirit of the disclosure, features in several different embodiments may be replaced, reorganized, and mixed to complete other embodiments. As long as the features of the embodiments do not violate the spirit of the invention or are not conflicting, the features may be arbitrarily mixed and matched for use.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

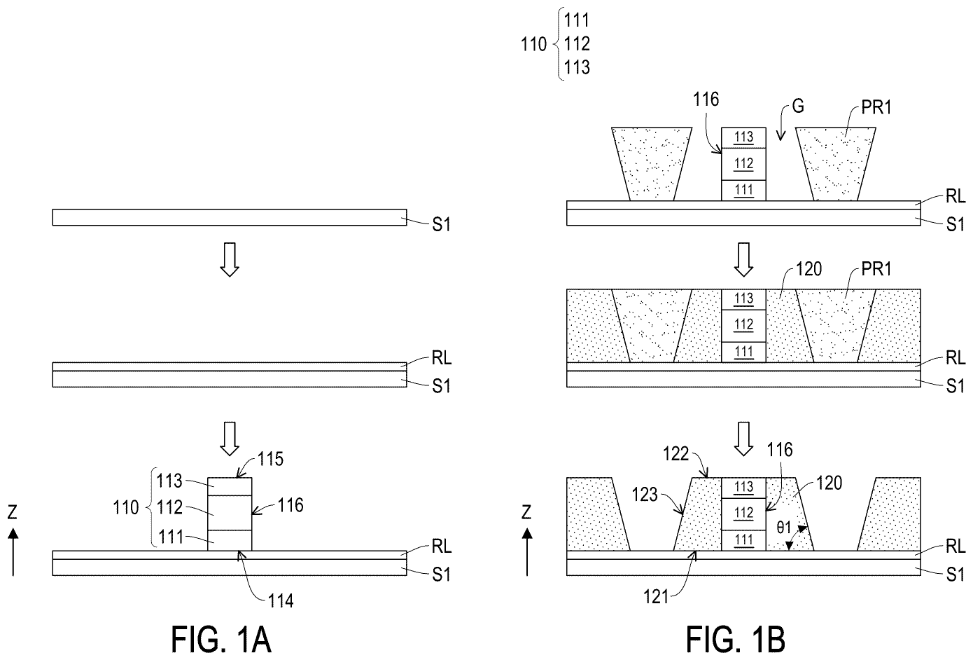

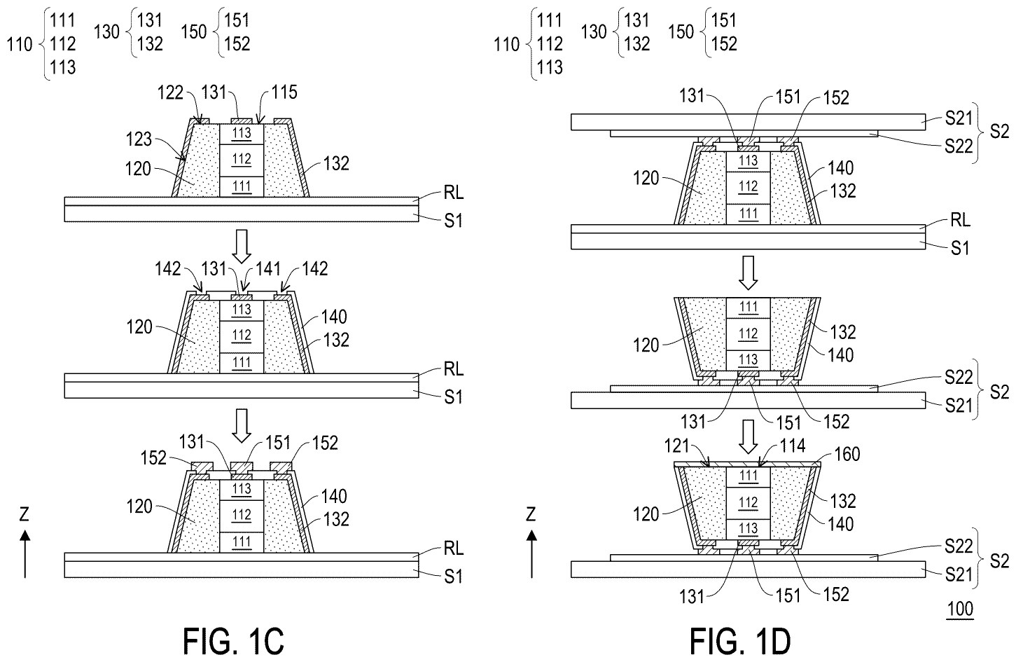

FIG. 1A to FIG. 1D are cross-sectional schematic views of the method of manufacturing a semiconductor chip in the first embodiment of the disclosure. The method of manufacturing a semiconductor chip 100 of the embodiment may include the following steps:

First, refer to FIG. 1A, a first carrier S1 is provided; then, a sacrificial layer RL is formed on the first carrier S1; subsequently, a semiconductor die 110 is transferred to the first carrier S1.

Specifically, in the embodiment, the first carrier S1 may include a rigid substrate, a flexible substrate, or a combination thereof. For example, the material of the first carrier S1 may include glass, quartz, sapphire, ceramic, polycarbonate (PC), polyimide (PI), polyethylene terephthalate (PET), epoxy, other suitable carrier materials, or a combination thereof, but not limited thereto.

The sacrificial layer RL is disposed between the semiconductor die 110 and the first carrier S1. The sacrificial layer RL may be removed together with the first carrier S1 in subsequent steps. In the embodiment, the material of the sacrificial layer RL may include adhesive materials that lose their adhesive properties when heated or exposed to ultraviolet light, or easily removable materials such as silicon nitride or silicon dioxide, but not limited thereto.

The semiconductor die 110 may be a vertical type chip. In a direction Z (for example, a normal direction of the first carrier S1), the semiconductor die 110 sequentially includes a first type semiconductor layer 111, an active layer 112, and a second type semiconductor layer 113 from bottom to top. The first type semiconductor layer 111 is closer to the first carrier S1 than the second type semiconductor layer 113, and the active layer 112 is disposed between the first type semiconductor layer 111 and the second type semiconductor layer 113. The semiconductor die 110 has a surface 114, another surface 115, and a side surface 116. The surface 114 and the another surface 115 are opposite to each other, the surface 114 is closer to the first carrier S1 than the another surface 115, and the side surface 116 connects the surface 114 and the another surface 115. In the embodiment, the semiconductor die 110 may be a light emitting component (for example, an organic light emitting diode, a mini light emitting diode, a micro light emitting diode, or a quantum dot light emitting diode, but not limited thereto), but not limited thereto. In the embodiment, the first type semiconductor layer 111 may be a P-type semiconductor layer, and the second type semiconductor layer 113 may be an N-type semiconductor layer, but not limited thereto. In some embodiments, the first type semiconductor layer may also be an N-type semiconductor layer, and the second type semiconductor layer may also be a P-type semiconductor layer. In the embodiment, the active layer 112 may be a light emitting layer, but not limited thereto.

Then, refer to FIG. 1B, a negative photoresist PR1 is formed on the sacrificial layer RL; subsequently, a filling layer 120 is formed on the side surface 116 of the semiconductor die 110 and the sacrificial layer RL exposed by the negative photoresist PR1; afterwards, the negative photoresist PR1 is removed.

Specifically, before forming the filling layer 120, the negative photoresist PR1 may expose the semiconductor die 110 and part of the sacrificial layer RL, and there is a gap G between the negative photoresist PR1 and the semiconductor die 110. The shape of the negative photoresist PR1 may be an inverted trapezoid. In the embodiment, the material of the negative photoresist PR1 may include acrylic, epoxy, siloxane, or silicon dioxide, but not limited thereto.

The filling layer 120 may surround and contact the side surface 116 of the semiconductor die 110. The filling layer 120 may include a first surface 121, a second surface 122, and a side surface 123. The first surface 121 is opposite to the second surface 122, and the first surface 121 is closer to the first carrier S1 than the second surface 122. The side surface 123 is disposed between the first surface 121 and the second surface 122, and the side surface 123 connects the first surface 121 and the second surface 122. In the embodiment, an angle θ1 between the first surface 121 and the side surface 123 has a taper angle. The angle θ1 may be 10 degrees to 80 degrees, or 30 degrees to 70 degrees, to concentrate the light emission of the semiconductor die 110, reduce the light emission angle of the semiconductor die 110, or improve the light emission efficiency of the semiconductor die 110, but not limited thereto. In the embodiment, the material of the filling layer 120 may include acrylic, epoxy, siloxane, silicon dioxide, other transparent filling materials, or a combination thereof, but not limited thereto.

Then, refer to FIG. 1C, a reflective layer 130 is formed on the semiconductor die 110 and the side surface 123 of the filling layer 120; subsequently, an insulating layer 140 is formed on the reflective layer 130; afterwards, an electrode layer 150 is formed on the reflective layer 130.

Specifically, the reflective layer 130 includes a first part 131 and a second part 132. The first part 131 is disposed on the another surface 115 of the semiconductor die 110. The first part 131 may contact and be electrically connected to the second type semiconductor layer 113 of the semiconductor die 110. The second part 132 is disposed on the filling layer 120. The second part 132 is disposed on the side surface 123 and the second surface 122 of the filling layer 120. The second part 132 is separated from the first part 131. In the embodiment, the material of the reflective layer 130 may include materials with high reflective characteristics, to concentrate the light emission of the semiconductor die 110, reduce the light emission angle of the semiconductor die 110, or improve the light emission efficiency of the semiconductor die 110.

The insulating layer 140 surrounds the reflective layer 130, and the insulating layer 140 may separate the first part 131 and the second part 132 of the reflective layer 130. The insulating layer 140 has an opening 141 and an opening 142. The opening 141 may expose part of the first part 131, and the opening 142 may expose part of the second part 132. In the embodiment, the material of the insulating layer 140 may include acrylic, epoxy, siloxane, silicon dioxide, silicon nitride, silicon oxynitride, other suitable insulating materials, or a combination thereof, but not limited thereto.

The electrode layer 150 includes a first electrode 151 and a second electrode 152. The first electrode 151 and the second electrode 152 are separated from each other. The first electrode 151 is disposed on the insulating layer 140 and in the opening 141 of the insulating layer 140, and the first electrode 151 may connect to the first part 131. The second electrode 152 is disposed on the insulating layer 140 and in the opening 142 of the insulating layer 140, and the second electrode 152 may connect to the second part 132. In the embodiment, the material of the electrode layer 150 may include gold, tin, copper, other suitable electrode materials, or a combination thereof, but not limited thereto. In the embodiment, the first electrode 151 may be a N-type electrode, and the second electrode 152 may be a P-type electrode, but not limited thereto. In some embodiments, the first electrode may also be a P-type electrode, and the second electrode may also be an N-type electrode. Herein, the N-type electrode refers to an electrode electrically connected to the N-type semiconductor layer, and the P-type electrode refers to an electrode electrically connected to the P-type semiconductor layer.

Then, refer to FIG. 1D, the second carrier S2 is attached to the electrode layer 150; subsequently, after flipping upside down, the first carrier S1 is removed to transfer the semiconductor die 110 from the first carrier S1 to the second carrier S2; afterwards, a conductive layer 160 is formed on the surface 114 of the semiconductor die 110.

Specifically, the second carrier S2 includes a substrate S21 and a circuit layer S22. The circuit layer S22 is disposed between the substrate S21 and the electrode layer 150. The circuit layer S22 may include metal traces (not shown), and the circuit layer S22 may be used to drive the semiconductor die 110. In the embodiment, the substrate S21 may include a rigid substrate, a flexible substrate, or a combination thereof. For example, the material of the substrate S21 may include glass, quartz, sapphire, ceramic, polycarbonate, polyimide, polyethylene terephthalate, other suitable substrate materials, or a combination thereof, but not limited thereto.

In the embodiment, for example, by applying laser to the sacrificial layer RL, the sacrificial layer RL may be separated from the semiconductor die 110, and the sacrificial layer RL and the first carrier S1 are removed.

The conductive layer 160 is disposed on the surface 114 of the semiconductor die 110 and on the first surface 121 of the filling layer 120. The conductive layer 160 may connect to the second part 132 of the reflective layer 130, and the conductive layer 160 may contact and be electrically connected to the first type semiconductor layer 111 of the semiconductor die 110. Thereby, the first type semiconductor layer 111 of the semiconductor die 110 may be electrically connected to the second electrode 152 through the conductive layer 160 and the second part 132. In the embodiment, the material of the conductive layer 160 may include transparent conductive oxides (TCO), graphene or metal, but not limited thereto. The material of the transparent conductive oxides may include indium tin oxide (ITO), indium zinc oxide (IZO) or indium gallium oxide (IGO) or a combination thereof, but not limited thereto. The metal may include thin metal or metal mesh, for example, a very thin metal layer (e.g., magnesium layer or silver layer) may be formed, or a metal mesh layer with light-transmitting openings may be formed by screen printing or other patterning processes. In some embodiments, the conductive layer 160 is a transparent conductive layer.

In the embodiment, the step of forming the conductive layer 160 may be after the step of forming the reflective layer 130, but not limited thereto. In some embodiments, the step of forming the conductive layer 160 may also be before the step of forming the reflective layer 130.

At this point, the semiconductor chip 100 in the embodiment has been substantially manufactured.

In the embodiment, since the first type semiconductor layer 111 and the second type semiconductor layer 113 of the vertical semiconductor die 110 may be electrically connected to the second electrode 152 and the first electrode 151 respectively, and the second electrode 152 and the first electrode 151 may be disposed on the same side of the semiconductor chip 100, the semiconductor chip 100 may be directly detected or process monitored after the semiconductor chip is transferred to the second carrier S2, thereby improving the transfer yield.

In the embodiment, since the semiconductor chip 100 may be a vertical embedded flip-chip (VEFC), the semiconductor chip 100 may be directly detected or process monitored after the semiconductor chip is transferred to the second carrier S2, thereby improving the transfer yield.

Other embodiments will be listed below as illustrations. It must be noted here that the following embodiments continue to use the reference numerals and some content of the foregoing embodiments, wherein the same numerals are adopted to represent the same or similar elements, and the description of the same technical content is omitted. For the description of the omitted part, reference may be made to the foregoing embodiments and will not be repeated in the following embodiments.

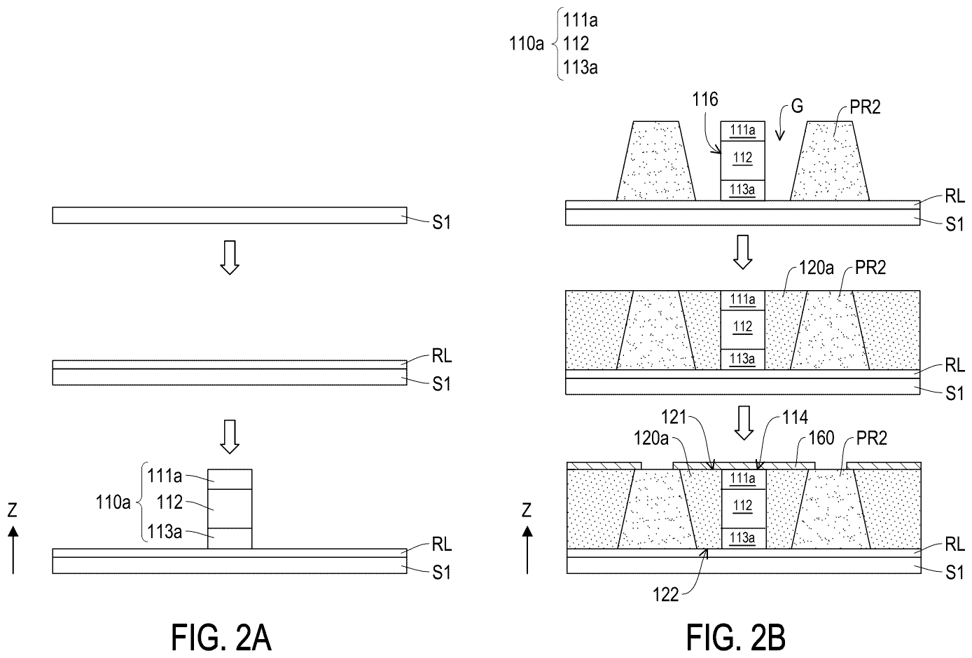

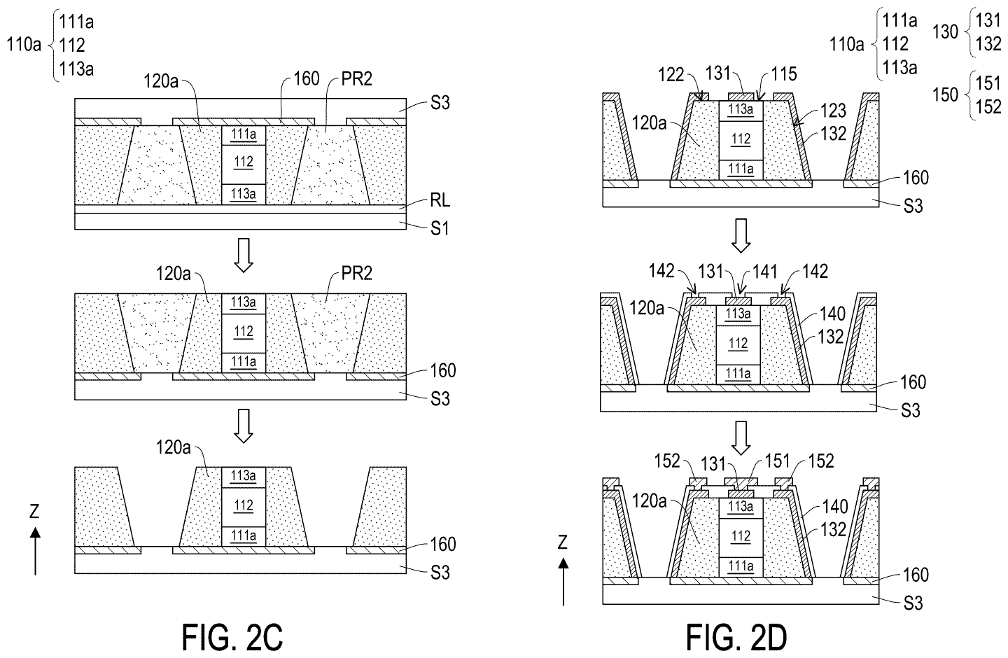

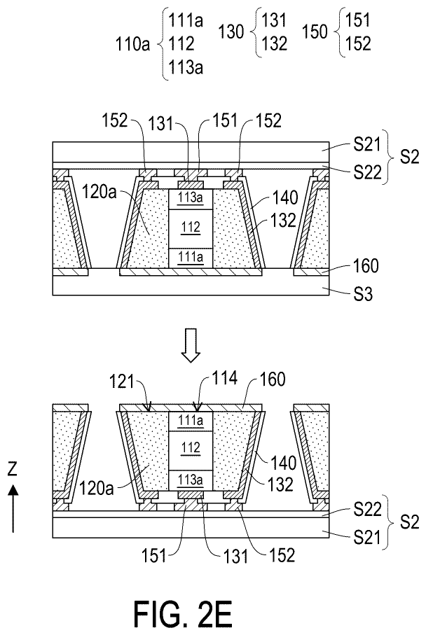

FIG. 2A to FIG. 2E are cross-sectional schematic views of the method of manufacturing a semiconductor chip in the second embodiment of the disclosure. The second embodiment shown in FIG. 2A to FIG. 2E is similar to the first embodiment shown in FIG. 1A to FIG. 1D, therefore, the same or similar components may adopt the same materials or methods. Hence, the same and similar descriptions in the two embodiments will not be repeated below, and the difference between the two embodiments will be mainly illustrated.

The method of manufacturing a semiconductor chip 100a in the embodiment may include the following steps:

First, refer to FIG. 2A, a first carrier S1 is provided; then, a sacrificial layer RL is formed on the first carrier S1; next, a semiconductor die 110a is transferred to the first carrier S1. In the embodiment, in the direction Z (for example, the normal direction of the first carrier S1), the semiconductor die 110a sequentially includes a second type semiconductor layer 113a, an active layer 112, and a first type semiconductor layer 111a from bottom to top. The second type semiconductor layer 113a is closer to the first carrier S1 than the first type semiconductor layer 111a, and the active layer 112 is disposed between the first type semiconductor layer 111a and the second type semiconductor layer 113a.

Then, refer to FIG. 2B, a positive photoresist PR2 is formed on the sacrificial layer RL; next, a filling layer 120a is formed on the side surface 116 of the semiconductor die 110a and on the sacrificial layer RL exposed by a positive photoresist PR2; then, a conductive layer 160 is formed on the surface 114 of the semiconductor die 110a and the first surface 121 of the filling layer 120a. In the embodiment, the shape of the positive photoresist PR2 may be a positive trapezoid, and the material of the positive photoresist PR2 may include acrylic, epoxy, siloxane, or silicon dioxide, but not limited thereto. In the embodiment, the second surface 122 of the filling layer 120a is closer to the first carrier S1 than the first surface 121.

Then, refer to FIG. 2C, a third carrier S3 is attached to the conductive layer 160; next, after flipping upside down, the first carrier S1 is removed; then, the positive photoresist PR2 is removed.

Then, refer to FIG. 2D, a reflective layer 130 is formed on another surface 115 of the semiconductor die 110a, the side surface 123 of the filling layer 120a, and the second surface 122 of the filling layer 120a; next, an insulating layer 140 is formed on the reflective layer 130; then, a first electrode 151 and a second electrode 152 of the electrode layer 150 are formed on the reflective layer 130.

Then, refer to FIG. 2E, the second carrier S2 is attached to the electrode layer 150; next, after flipping upside down, the third carrier S3 is removed to transfer the semiconductor die 110a from the third carrier S3 to the second carrier S2.

At this point, the semiconductor chip 100a in the embodiment has been substantially manufactured.

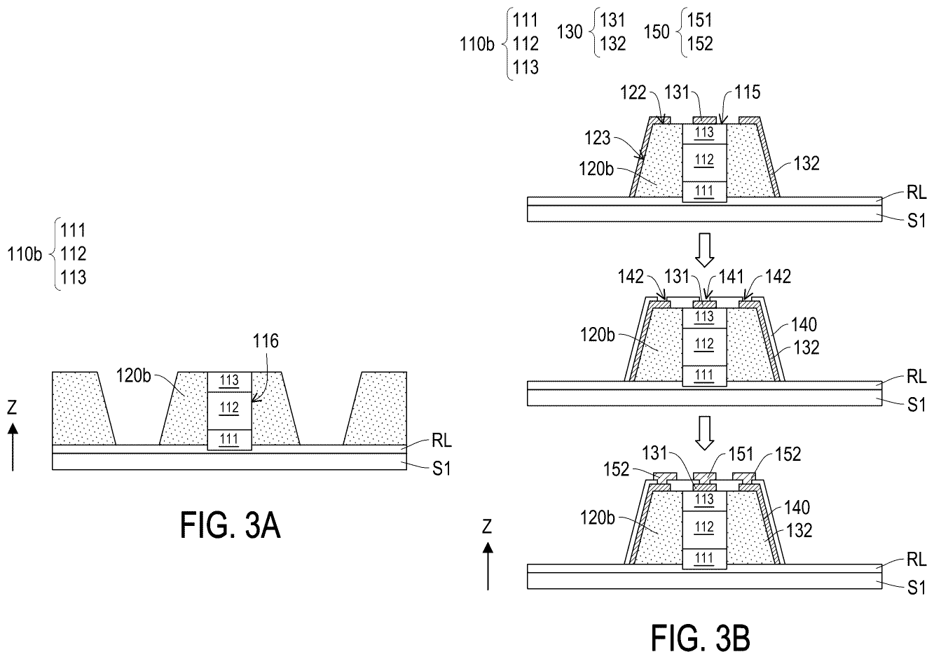

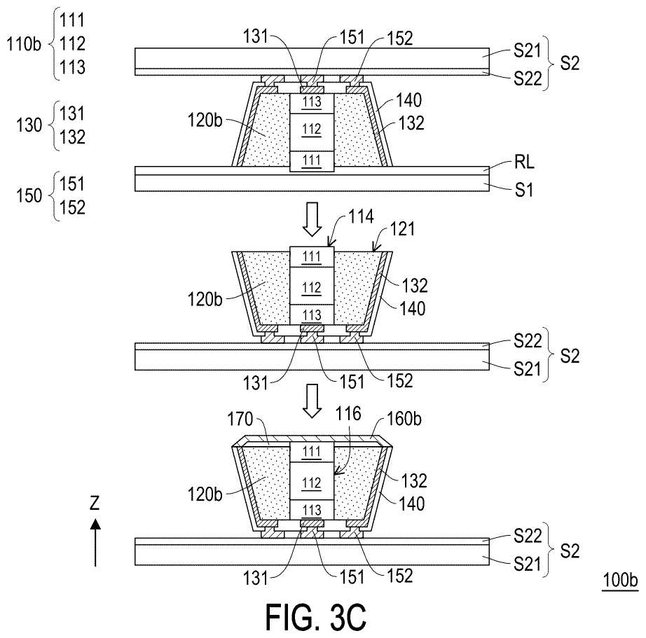

FIG. 3A to FIG. 3C are cross-sectional schematic views of the method of manufacturing a semiconductor chip in the third embodiment of the disclosure. The third embodiment shown in FIG. 3A to FIG. 3C is similar to the first embodiment shown in FIG. 1A to FIG. 1D, therefore, the same or similar components may adopt the same materials or methods. Hence, the same and similar descriptions in the two embodiments will not be repeated below, and the difference between the two embodiments will be mainly illustrated.

The method of manufacturing a semiconductor chip 100b in the embodiment may include the following steps:

First, refer to FIG. 3A, similar to the steps in FIG. 1A, after providing a first carrier S1 and forming a sacrificial layer RL on the first carrier S1, the semiconductor die 110b is transferred to the first carrier S1, and the semiconductor die 110b is partially embedded in the sacrificial layer RL. Then, the step of using the negative photoresist in FIG. 1B is omitted, the patterning process is directly performed after the filling layer 120b is disposed on the side surface 116 of the semiconductor die 110b.

Then, refer to FIG. 3B, a reflective layer 130 is formed on another surface 115 of the semiconductor die 110b, the side surface 123 of the filling layer 120b, and the second surface 122 of the filling layer 120b; next, an insulating layer 140 is formed on the reflective layer 130; then, a first electrode 151 and a second electrode 152 of the electrode layer 150 are formed on the reflective layer 130.

Then, refer to FIG. 3C, the second carrier S2 is attached to the electrode layer 150; next, after flipping upside down, the first carrier S1 is removed to transfer the semiconductor die 110b from the first carrier S1 to the second carrier S2; then, before the step of forming the conductive layer 160b, an insulating layer 170 is formed on the side surface 116 of the semiconductor die 110b where the filling layer 120b is not formed; next, after the step of forming the insulating layer 170, the conductive layer 160b is formed on the insulating layer 170, and the conductive layer 160b is connected to the second part 132 of the reflective layer 130. In the embodiment, the insulating layer 170 may be a single-layer structure or a multi-layer structure, and the material of the insulating layer 170 may include organic materials, inorganic materials, or a combination thereof, but not limited thereto.

At this point, the semiconductor chip 100b in the embodiment has been substantially manufactured.

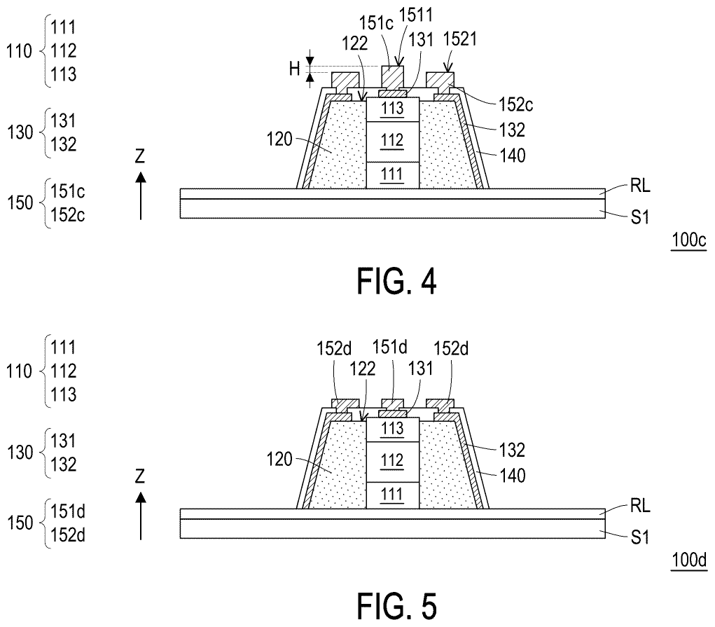

FIG. 4 is a cross-sectional schematic view of the semiconductor chip in the fourth embodiment of the disclosure. Please refer to FIG. 4 and FIG. 1C at the same time. A semiconductor chip 100c in the embodiment is similar to the semiconductor chip 100 in FIG. 1C. The only difference between the two is that in the semiconductor chip 100c of the embodiment, in the direction Z (for example, the normal direction of the first carrier S1), the first electrode 151c may be higher than the second electrode 152c.

Specifically, refer to FIG. 4, in the direction Z, another surface 115 of the semiconductor die 110 is higher than the second surface 122 of the filling layer 120, and the first part 131 of the reflective layer 130 is higher than the second part 132.

The first electrode 151c has a surface 1511 facing away from the semiconductor die 110, and the second electrode 152c has a surface 1521 facing away from the semiconductor die 110. In the direction Z, a height difference H between the first electrode 151c and the second electrode 152c may be greater than 0 and less than or equal to 1 micrometer (μm) (that is, 0<H≤1 μm), but not limited thereto. The height difference H is, for example, the minimum distance measured along the direction Z between the surface 1511 of the first electrode 151c and the surface 1521 of the second electrode 152c.

FIG. 5 is a cross-sectional schematic view of the semiconductor chip in the fifth embodiment of the disclosure. Please refer to FIG. 5 and FIG. 4 at the same time. A semiconductor chip 100d in the embodiment is similar to the semiconductor chip 100c in FIG. 4. The only difference between the two is that in the semiconductor chip 100d of the embodiment, the first electrode 151d and the second electrode 152d are formed respectively by different steps, so that the first electrode 151d and the second electrode 152d may be substantially equal in height in the direction Z (for example, the normal direction of the first carrier S1).

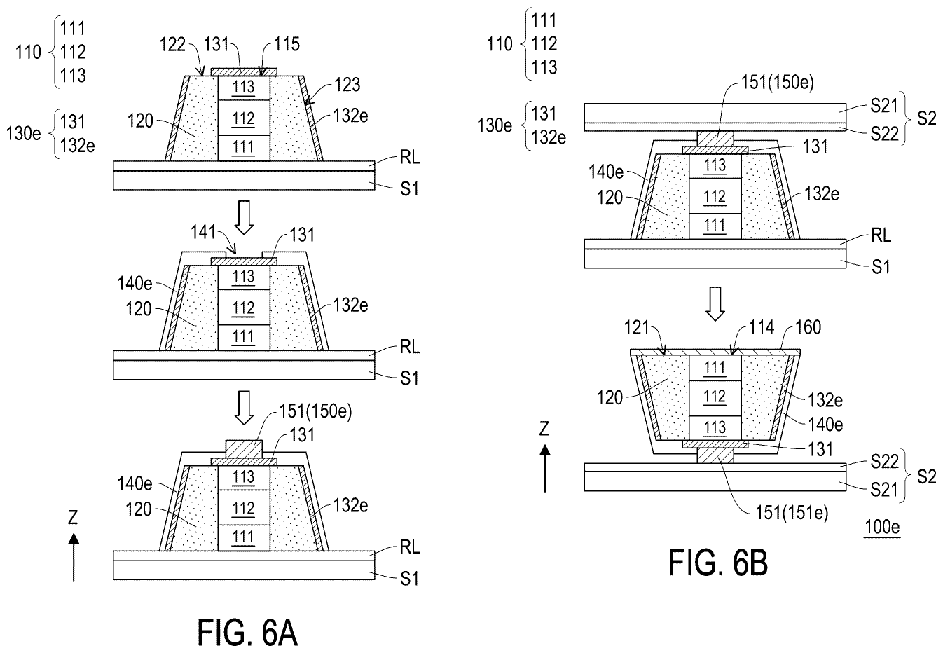

FIG. 6A to FIG. 6B are cross-sectional schematic views of the semiconductor chip in the sixth embodiment of the disclosure. FIG. 6A to FIG. 6B are steps that continue from FIG. 1B and replace FIG. 1C to FIG. 1D. The same or similar components in the sixth embodiment of FIG. 6A to FIG. 6B and the embodiment of FIG. 1A to FIG. 1D may adopt the same materials or methods. Therefore, the same and similar descriptions in the two embodiments will not be repeated below, and the difference between the two embodiments will be mainly illustrated.

The method of manufacturing the semiconductor chip 100e in the embodiment may include the following steps:

First, refer to FIG. 6A, after forming the structure of FIG. 1B, the first part 131 of the reflective layer 130e is formed on another surface 115 of the semiconductor die 110, and the second part 132e of the reflective layer 130e is formed on the side surface 123 of the filling layer 120; then, the insulating layer 140e is formed on the reflective layer 130e, wherein the insulating layer 140e has an opening 141 that may expose part of the first part 131; then, the first electrode 151 of the electrode layer 150e is formed on the insulating layer 140e and in the opening 141 of the insulating layer 140e.

Then, refer to FIG. 6B, the second carrier S2 is attached to the electrode layer 150e; next, after flipping upside down, the first carrier S1 is removed to transfer the semiconductor die 110 from the first carrier S1 to the second carrier S2; then, a conductive layer 160 is formed on the surface 114 of the semiconductor die 110.

At this point, the semiconductor chip 100e in the embodiment has been substantially manufactured. The semiconductor chip 100e of the embodiment may be considered as a vertical embedded chip (VEC), but not limited thereto.

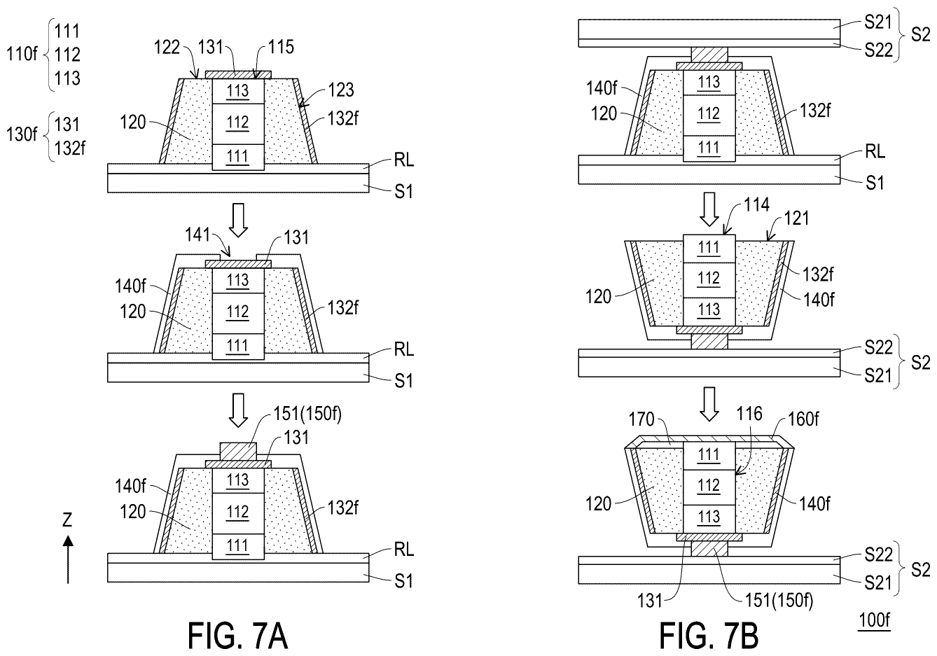

FIG. 7A to FIG. 7B are cross-sectional schematic views of the semiconductor chip in the seventh embodiment of the disclosure. The seventh embodiment shown in FIG. 7A to FIG. 7B is similar to the sixth embodiment shown in FIG. 6A to FIG. 6B, therefore, the same or similar components may adopt the same materials or methods. Hence, the same and similar descriptions in the two embodiments will not be repeated below, and the difference between the two embodiments will be mainly illustrated.

The method of manufacturing the semiconductor chip 100f in the embodiment may include the following steps:

First, refer to FIG. 7A, the semiconductor die 110f of the embodiment may be partially embedded in the sacrificial layer RL; then, following steps similar to FIG. 6A, the first part 131 of the reflective layer 130f is formed on another surface 115 of the semiconductor die 110f, and the second part 132f of the reflective layer 130f is formed on the side surface 123 of the filling layer 120; then, the insulating layer 140f is formed on the reflective layer 130f, wherein the insulating layer 140f has an opening 141 that may expose part of the first part 131; then, the first electrode 151 of the electrode layer 150f is formed on the insulating layer 140f and in the opening 141 of the insulating layer 140f.

Then, refer to FIG. 7B, the second carrier S2 is attached to the electrode layer 150f; next, after flipping upside down, the first carrier S1 is removed to transfer the semiconductor die 110f from the first carrier S1 to the second carrier S2; then, before forming the conductive layer 160f, an insulating layer 170 is formed on the side surface 116 of the semiconductor die 110f where the filling layer 120 is not formed; after forming the insulating layer 170, the conductive layer 160f is formed on the insulating layer 170, and the conductive layer 160f is connected to the second part 132 of the reflective layer 130f. In the embodiment, the insulating layer 170 may be a single-layer structure or a multi-layer structure, and the material of the insulating layer 170 may include organic materials, inorganic materials, or a combination thereof, but not limited thereto.

At this point, the semiconductor chip 100f in the embodiment has been substantially manufactured.

In summary, in the method of manufacturing the semiconductor chip of the embodiments of the disclosure, since the first type semiconductor layer and the second type semiconductor layer of the vertical semiconductor die may be electrically connected to the second electrode and the first electrode respectively, and the second electrode and the first electrode may be disposed on the same side of the semiconductor chip, the semiconductor chip in the electronic device may be directly detected or process monitored after the semiconductor chip is transferred to the first circuit layer, thereby improving the transfer yield.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A method of manufacturing a semiconductor chip, comprising:
providing a first carrier;
transferring a semiconductor die to the first carrier, wherein the semiconductor die has a surface and another surface opposite to each other;
forming a filling layer on a side surface of the semiconductor die;
forming a reflective layer on the semiconductor die and the side surface, wherein the reflective layer comprises:
a first part, disposed on the surface of the semiconductor die; and
a second part, disposed on the filling layer; and
forming a conductive layer on the another surface of the semiconductor die.

2. The method according to claim 1, wherein the conductive layer connects the second part of the reflective layer.

3. The method according to claim 1, further comprising:
transferring the semiconductor die from the first carrier to a second carrier.

4. The method according to claim 1, further comprising:
forming an electrode layer on the reflective layer, wherein the electrode layer comprises a first electrode connected to the first part.

5. The method according to claim 4, wherein the filling layer comprises a first surface, a second surface and a side surface, the side surface is disposed between the first surface and the second surface, and the second part is disposed on the side surface and the second surface of the filling layer.

6. The method according to claim 5, wherein the electrode layer further comprises a second electrode connected to the second part.

7. The method according to claim 6, wherein the first electrode and the second electrode are disposed on the same side of the semiconductor chip.

8. The method according to claim 4, wherein the filling layer comprises a first surface, a second surface and a side surface, the side surface is disposed between the first surface and the second surface, and the second part is disposed on the side surface of the filling layer.

9. The method according to claim 1, wherein the filling layer surrounds the side surface of the semiconductor die.

10. The method according to claim 1, wherein the filling layer comprises a first surface, a second surface and a side surface, the side surface is disposed between the first surface and the second surface, and an angle between the first surface and the side surface is 10 degrees to 80 degrees.

11. The method according to claim 1, wherein the semiconductor die comprises a first type semiconductor layer, an active layer and a second type semiconductor layer, and the first type semiconductor layer is electrically connected to the conductive layer.

12. The method according to claim 11, wherein the second type semiconductor layer is electrically connected to the first part.

13. The method according to claim 1, wherein the first part and the second part of the reflective layer are separated from each other.

14. The method according to claim 1, further comprising:
forming a sacrificial layer on the first carrier; and
partially embedding the semiconductor die into the sacrificial layer.

15. The method according to claim 14, further comprising:
before the step of forming the conductive layer, forming an insulating layer on the side surface of the semiconductor die where the filling layer is not formed.

16. The method according to claim 15, further comprising:
after the step of forming the insulating layer, forming the conductive layer on the insulating layer, and connecting the conductive layer to the second part of the reflective layer.

17. The method according to claim 1, wherein the step of forming the conductive layer is after the step of forming the reflective layer.

18. The method according to claim 1, wherein the step of forming the conductive layer is before the step of forming the reflective layer.

19. The method according to claim 1, wherein the semiconductor chip is a vertical embedded flip-chip or a vertical embedded chip.

20. The method according to claim 1, wherein the semiconductor chip is a light emitting component.
